(19) United States
(12) Patent Application Publication
(10) Pub. No.: US 2025/0130494 A1
(43) Pub. Date: Apr. 24, 2025

(54) POSITIVE TYPE PHOTOSENSITIVE RESIN COMPOSITION AND METHODS OF MAKING SAME

(71) Applicant: Akron Polymer Systems, Inc., Akron, OH (US)

(72) Inventors: Yufeng Zhu, Highland Heights, OH (US); Lang Hu, Tallmadge, OH (US); Zhen Li, Hudson, OH (US); Limin Sun, Copley, OH (US); Dong Zhang, Hudson, OH (US); Xiaoliang Zheng, Hudson, OH (US)

(73) Assignee: Akron Polymer Systems, Inc., Akron, OH (US)

(21) Appl. No.: 18/609,112

(22) Filed: Mar. 19, 2024

Related U.S. Application Data
(60) Provisional application No. 63/592,757, filed on Oct. 24, 2023.

(51) Int. Cl. G03F 7/039; C08G 73/10; G03F 7/004

(52) U.S. Cl. CPC G03F 7/039; C08G 73/1053; G03F 7/0045

(57) ABSTRACT

The components and methods disclosed herein are directed to positive type photosensitive resin compositions, which are comprised of an alkynyl containing polymer, a benzophenone type DNQ, and solvents. The alkynyl containing polymer is prepared by the condensation reaction of alkynyl containing dianhydrides and hydroxyl containing diamines, and alkynyl containing end cappers. The advantage of this formulation is that the resulting photosensitive resin composition is comprised of only a polymer, a benzophenone type DNQ PAC, and solvents that generates high resolution patterned films with good thermal and physical properties without using additional additives. This composition also enables film curing at relatively low temperatures without additional additives, simplifying the composition. After curing, the alkynyl units in the polymer chain and the chain ends give the cured film excellent solvent resistance and film retention due to intra and/or inter-molecular crosslinking.

### CROSS-REFERENCE TO RELATED APPLICATIONS

The present application claims priority to U.S. provisional application Ser. No. 63/592,757, titled “Positive Type Photosensitive Resin Composition and Methods of Making Same,” filed Oct. 24, 2023, which is fully hereby incorporated by reference herein.

### FIELD OF INVENTION

This disclosure is generally related to the semiconductor and display technology fields, and this disclosure is specifically related to a positive type photosensitive resin composition and methods of making same.

### BACKGROUND

The continued use and development of mobile electronic devices in the marketplace has driven the continued development of display technologies to improve a number of attributes such as color range, increased contrast, reduced thickness, lower cost, and improved user experience. Current technology uses films made from cured polyimide or polybenzoxazole containing photosensitive resin compositions as an organic insulating and planarization layer in semiconductor and display devices.

The thermal, mechanical, and solvent resistance of positive type photosensitive polyimides have been shown in the market. Diazonaphthoquinone (“DNQ”) type photoactive compounds (“PAC” or “PACs”) are typically added into the composition as a dissolution inhibitor to increase the dissolution contrast between the exposed and unexposed regions, enabling high resolution patterns to be obtained after film development. Previously, hydroxylated polyimide precursors were formulated with DNQ PACs to form positive type photosensitive resin compositions. Such polymers show alkaline solubility, but the resolution and photosensitivity are limited due to the high molecular weights of the polymers used. Additionally, thermal shrinkage is an issue. The limited resolution and photosensitivity of these formulations encourage exploration of lower molecular weight polymers. Although this improves the resolution and photosensitivity, crosslinking additives, e.g., alkoxyl methyl containing crosslinkers, have to be introduced to the formulation to improve the thermal and physical properties of the final films. The additional additives introduced more cost and potential compatibility issues, which lead to surface defects and poor adhesion. There is a need in the industry for improved photosensitive resin compositions and methods of making such compositions for use in the semiconductor and display technology fields. The photosensitive resin compositions and methods of making such compositions address that need.

### SUMMARY

The components and methods disclosed herein are directed to a positive photosensitive resin composition that has the ability to form high resolution patterns with good film retention and solvent resistance using low molecular weight, alkynyl containing polymers and benzophenone PACs without additional crosslinking agents. Taking advantage of the reactivity of alkynyl and benzophenone structures, additional crosslinking agents are unnecessary to obtain low temperature cured films with good solvent resistance and low shrinkage.

More specifically, the components and methods disclosed herein are directed to positive type photosensitive resin compositions, which are comprised of an alkynyl containing polymer, a benzophenone type DNQ, and solvents. The alkynyl containing polymer is prepared by the condensation reaction of alkynyl containing dianhydrides and hydroxyl containing diamines, and alkynyl containing end cappers. The advantage of this formulation is that the resulting photosensitive resin composition is comprised of only a polymer, a benzophenone type DNQ PAC, and solvents that generates high resolution patterned films with good thermal and physical properties without using additional additives. This composition also enables film curing at relatively low temperatures without additional additives, simplifying the composition. After curing, the alkynyl units in the polymer chain and the chain ends give the cured film excellent solvent resistance and film retention due to intra and/or inter-molecular crosslinking.

### BRIEF DESCRIPTION OF THE DRAWINGS

FIG. 1 is an image of a line/space pattern of a sample that passes a solvent resistance test.

FIG. 2 is an image of a line/space pattern of a sample that fails a solvent resistance test.

### DETAILED DESCRIPTION

This disclosure is directed to positive type photosensitive resin compositions, which are comprised of an alkynyl containing polymer, a benzophenone type DNQ PAC, and solvents. The alkynyl containing polymer is prepared from the condensation of diamines and dianhydrides yielding a polyamic acid that may later be converted to a polyamic ester or polyimide. One or more of the dianhydride monomers and the chain ends contain alkynyl groups. The introduction of alkynyl groups enable the low-temperature, e.g. 250° C., crosslinking of this polymer without additional crosslinking agents. With the addition of a benzophenone type DNQ PAC as a dissolution inhibitor, this positive type photosensitive resin composition shows significant solubility contrast between photo-exposed and non-photo-exposed areas yielding a high-resolution film pattern after development. The patterned film shows excellent solvent resistance and film retention, which is beneficial in the organic insulating and/or planarization layers in display and semiconductor devices.

Specifically, the dianhydride used herein includes 4,4′-(ethyne-1,2-diyl) diphthalic anhydride (“EDDPA”) with the possible addition of more comonomers. The comonomers could be, but not limited to, 4,4′-oxydiphthalic anhydride (ODPA), pyromelliticdianhydride (“PMDA”); 3,3′,4,4′-biphenyltetracarboxylic dianhydride (“BPDA”); 4,4′-(hexafluoroisopropylidene)-diphthalic anhydride (“6FDA”); 3,3′,4,4′-benzophenonetetracarboxylic dianhydride (“BTDA”); 3,3′,4,4′-diphenylsulfonetetracarboxylic dianhydride (“DSDA”); 4,4′-binaphthyl-1,1′,8,8′-tetracarboxylic dianhydride (“BNDA”); and 1,4,5,8-naphthalene-tetracarboxylic dianhydride (“NDA”).

The diamine used herein includes 2,2-Bis(3-amino-4-hydroxyphenyl) hexafluoropropane (“6FAP”) or 2,2-Bis(3-(3-aminobenzoylamino)-4-hydroxyphenyl) hexafluoropropane (“6FAPDA, A3”) with the possible addition of more comonomers. The other diamine comonomers can include, but are not limited to, p-phenylenediamine (“PDA”); 4,4′-oxydianiline (“ODA”); 2,2′-bis(trifluoromethyl)benzidine (“PFMB”); 2,4-diaminomesitylene (“DAM”); 1,5-naphthalenediamine (“DAN”); [1,1′-binaphthalene]-5,5′-diamine (“DABN”); 3,5-diethyl-toluene-2,6-diamine (“2,6-DETDA”); 3,5-diethyl-toluene-2,4-diamine (“2,4-DETDA”); and 4,4′-(9-fluorenylidene)dianiline) (“FRDA”).

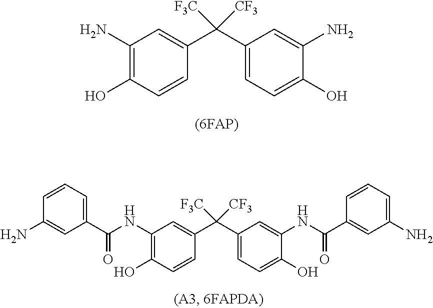 [SMILES: Nc1cc(C(c2ccc(O)c(N)c2)(C(F)(F)F)C(F)(F)F)ccc1O ; Nc1cccc(C(=O)Nc2cc(C(c3ccc(O)c(NC(=O)c4cccc(N)c4)c3)(C(F)(F)F)C(F)(F)F)ccc2O)c1]

The polymer endcapper contains an acetylene structure such as, but not limited to, 3-ethynylaniline (3EA) or 4-ethynylaniline (“4EA”).

The DNQ PAC contains a benzophenone type structure, such as, but not limited to, C1 and C2.

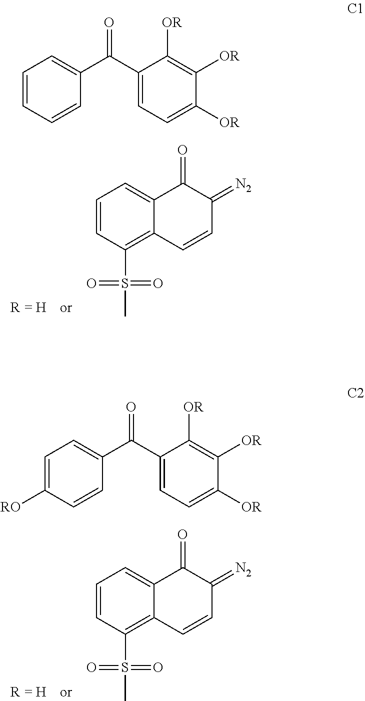

Combinations of the dianhydrides and diamines disclosed herein, can yield three kinds of positive type photosensitive polymers polyamic acids, polyamic esters, and polyimides. The preparation of these different types of polymers are different and these differences are described below.

The following describes one example of the synthesis of polyamic acid (“PAA). First mix the dianhydride and diamine in a solvent and allow condensation polymerization to occur at 0-70° C. for 1-12 hours. The solvent can be one or a mixture of solvents such as, but not limited to, NMP, γ-GBL, DMAc, and DMF. The quantity of the solvent can be 1-10 times the weight of the solids. Add the DNQ PAC to this solution to make the positive photosensitive composition. The polyamic acid solid can be isolated by drying the solution under reduced pressure or by adding non-solvents, precipitating it, filtering it, and then drying the precipitate.

The following describes one example of the synthesis of polyamic ester (“PAE”). Allow the prepared PAA to heat with esterification reagents to convert the carboxylic acid groups to ester groups. The degree of esterification can be 10-90%, and the esterification temperature can be 20-80° C., while the esterification time can be 0.5-12 hours. Esterification reagents can be alcohols, such as, but not limited to, methanol or ethanol, or acetals, such as, but not limited to, N,N′-dimethylformamide dimethyl acetal (“DMFDMA”) or N,N′-dimethylformamide diethyl acetal (“DMFDEA”), with a carboxylic acid to esterification reagent molar ratio of 1:0.1-10.

The following describes one example of the synthesis of polyamic ester (“PAE”). Allow the prepared PAA to reflux 1-5 hours with chemical imidization reagents or heat the prepared PAA for 2-12 hours with an imidization catalyst. The PAA is converted to a polyimide by the ring closing reaction. The degree of imidization can be 10-100%, imidization temperature can be 20-210° C., 100-190° C. preferred, time of imidization can be 1-24 hours, with 2-8 hours preferred.

PAA, PAE, or PI are endcapped with acetylene type endcappers, including but not limited to acetylene containing primary amines, such as 3EA and 4EA.

The PAC used are 2,1,4 or 2,1,5-DNQ compounds, which are derived from esterification of DNQ sulfonyl chloride and phenol compounds. The phenol compounds are selected from one or more of benzophenone phenols, such as, but not limited to, 2,4-bihydroxybenzophenone; 2,3,4-trihydroxybenzophenone; 2,2′,4,4′-tetrahydroxybenzophenone; 2,3,4,4′-tetrahydroxybenzophenone; 4-hydroxybenzophenone; 4-Chloro-4′-hydroxybenzophenone; and 3-Chloro-4′-hydroxybenzophenone.

The solvent is one or a combination of solvents such as, but not limited to, γ-GBL, NMP, PGME, PGMEA, and EL.

The positive photosensitive resin composition is prepared by mixing the polymer resin with DNQ PACs and solvents, and the solution is then filtered to remove insoluble particles.

The following describes one example of the preparation of cured films from the photosensitive resin. Coat the positive photosensitive resin composition onto a substrate, which can be, but not limited to, a silicon wafer, glass plate or conductive glass plate. The surface of the substrate may be treated with an agent to modify the wettability of the substrate with respect to the positive photosensitive resin composition. The coating method may be, but not limited to, spin, spray, or roller coating. A typical dry film has a thickness of 0.5-3 μm. Film thickness may vary with solid content, viscosity, ambient temperature, relative humidity, etc. Prebake the wet film on a preheated hotplate. The temperatures and drying times vary with different solvent systems, typically the drying temperature is between 90-140° C. and drying time is 1-10 minutes. After the prebake step, apply the photomask with a pattern to the film, and expose with UV light, typically generated by a Hg lamp (I line or broadband).

The photo exposed film is then developed with an alkaline developer to reveal the pattern. Possible developer solutions include, but are not limited to, tetramethylammonium hydroxide (“TMAH”) aqueous solutions, preferably at 2.38 wt %. One or a combination of solvents can be added to the developer, including polar solvents such as, but not limited to, NMP, DMF, DMAc, DMSO, and γ-GBL; alcohols such as, but not limited to, methanol, ethanol, and isopropanol (“IPA”); esters such as, but not limited to EL and PGMEA; or ketones such as, but not limited to, cyclopentanone, cyclohexanone, MEK, and MIBK. After the development process, the film is rinsed with water. Solvents can be added to the rinsing water including alcohols such as, but not limited to, methanol, ethanol and IPA, or esters such as, but not limited to, EL and PGMEA.

The photo-exposed and developed film can be cured to a final temperature of 250-500° C., preferably 250° C., under nitrogen. The heating profile for thermal curing can involve a single temperature, step-wise heating, or treating the film for 30 minutes to 5 hours during a continuous heating process. For instance, the film could be treated by continuously heating at 250° C. for 1 hour, or at 120° C., 200° C., and 350° C. for 30 minutes each, or by ramping the temperature from ambient to 400° C. over 1 hour.

The advantage of the methods and compositions disclosed herein is that the simple positive photosensitive resin composition of an alkynyl containing polymer, a benzophenone type DNQ, and solvents creates high resolution patterned films with good film retention and solvent resistance without the presence of an additional additives. The alkynyl units in the polymer chain and the chain ends are able to react intra- and/or inter-molecularly, giving the final cured film excellent solvent resistance and film retention. The photosensitive film thereof can be cured at a low temperature without needing additional crosslinking agents. A high-resolution film pattern can be derived from this photosensitive resin. Patterned films from this invention could be used as passivation or protection layers in semiconductor devices and organic insulating or planarization layers in display devices.

The following are descriptions of experiments that can be conducted on compositions described and disclosed herein.

The following describes one example of the synthesis of positive photosensitive polymers for samples and comparative samples. To make photosensitive polymer P1, the following are added to a dry 3N flask: a solution of 3.140 g 6FAPDA and 29.10 g NMP, 1.432 g of ODPA and 0.367 g EDDPA. The mixture is allowed to stir at ambient temperature for 1 hour and then at 50° C. for 2 hours under N₂. Then 0.135 g 3EA is added and allowed to stir for an additional 2 hours at 50° C. Then 1.375 g DMFDMA in NMP (20 wt %) is added to the solution over 15 minutes. The reaction mixture is precipitated in deionized water after 30 minutes. The solid is filtered and washed with water six times, then dried at 80° C. for 24 hours under vacuum, giving a white powder. Positive photosensitive polymers P2-P5 are synthesized using a similar procedure but with the different compositions of dianhydrides, diamines, and endcappers listed in Table 1 below.

TABLE 1
Molar ratio of monomers and endcappers
used for polymer synthesis

| | Dianhydride 1 | Dianhydride 2 | Diamine | Endcapper |
|---|---|---|---|---|
| Polymer | (mol %) | (mol %) | (mol %) | (mol %) |
| P1 | A1 (20) | A2 (80) | A3 (90) | B1 (20) |
| P2 | A1 (20) | A2 (80) | A3 (90) | B2 (20) |
| P3 | A2 (100) | | A3 (90) | B1 (20) |
| P4 | A2 (100) | | A3 (90) | B2 (20) |
| P5 | A1 (50) | A2 (50) | A3 (90) | B3 (20) |

Chemical structures used in the samples and comparative sample compounds are listed below.

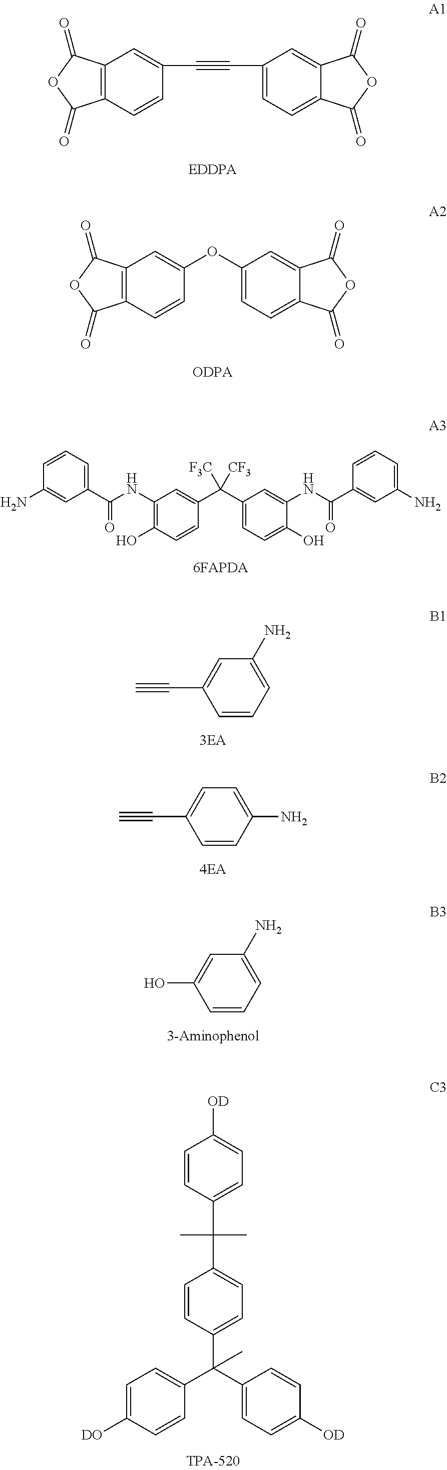

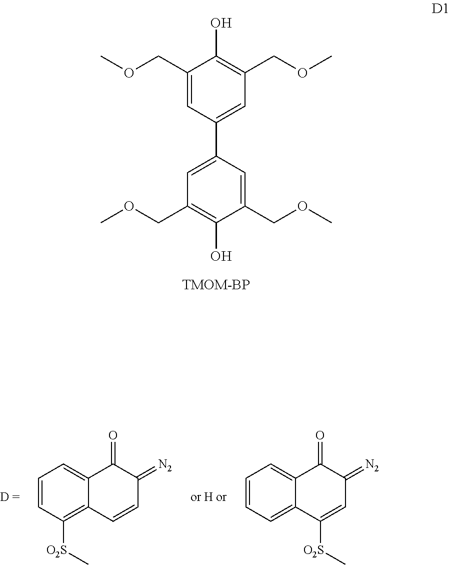

The following describes one example of the preparation of positive photosensitive samples and comparative samples compositions. To make positive photosensitive compositions for evaluation, the specified weight percentages of the photosensitive polymer, DNQ PAC, and solvent are added to a vessel under amber light and allowed to dissolve at ambient temperature. To concretely illustrate this, sample 1 is made by dissolving 8 grams of polymer P1 and 2 grams of DNQ PAC C1 in 90 grams NMP under amber light at ambient temperature. Preparation of other samples and comparative samples are similar but with different types and amounts of polymer, DNQ PAC, and solvents. The positive photosensitive compositions is then filtered through a 0.22 μm PTFE filter.

The following describes one example of the preparation of photosensitive film. The photosensitive compositions is cast on 4 inch×4 inch glass substrates, dried in a vacuum oven at 80-90° C. for 6 minutes, and then prebaked on a 120° C. hotplate for 2 minutes. The film thickness after prebaking is 1.8-2.2 μm.

The following describes one example for measuring thickness. The thickness of the photosensitive polymer film is measured with a Bruker Dektak DXT-E Profilometer at scratched spots.

The following describes one example of photo exposure and development. The prebaked films are photo exposed under a mask with an ABM 350W Exposing System (Hg lamp, broadband). The UV light intensity was 20 mW/cm² (vs. i-line). The exposure dose was 100 mJ/cm². The exposed films are developed with a 2.38% TMAH aqueous solution for 60 seconds at 25° C., followed by rinsing with water for 60 seconds. The patterned films are dried with compressed air. The film is examined with an optical microscope for pattern formation (Meiji Techno MT9430, 100× magnification).

The following describes one example for patterned film curing. The patterned films is cured in an oven at 250° C. under N₂. The thickness of the cured films is then measured with a Bruker Dektak DXT-E profilometer.

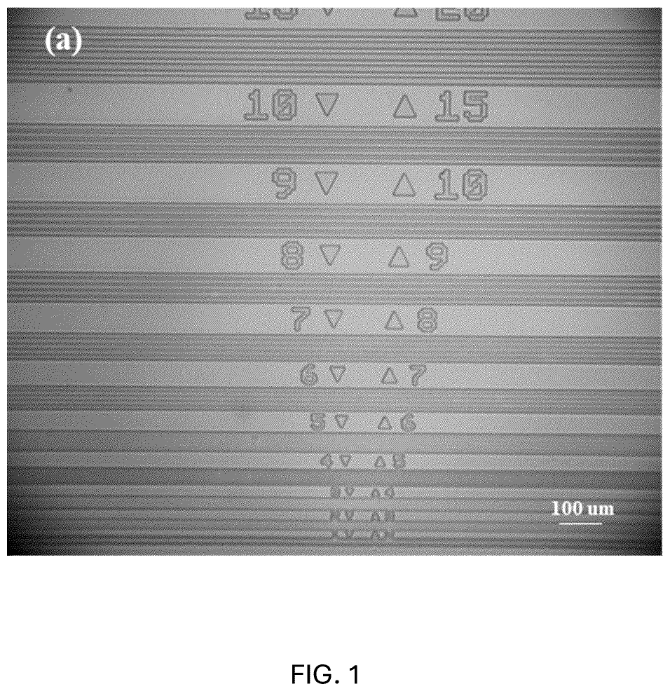

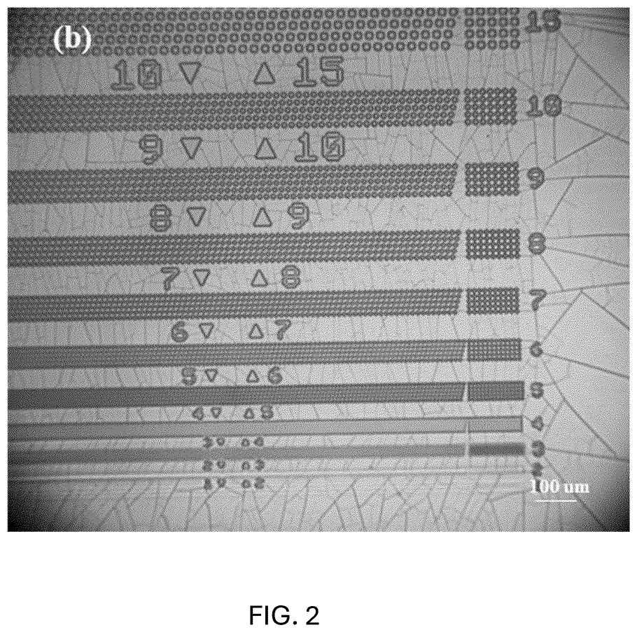

The following describes one example of solvent resistance testing. The cured films is immersed in an NMP bath for 10 minutes, followed by 60 seconds of water rinsing and then air drying. The films are then examined with an optical microscope for cracks (Meiji Techno MT9430, 100× magnification). If there are cracks in the film, the sample failed the solvent resistance test. Otherwise, the film passes the test. Exemplary images of films that passed and failed the solvent resistance test are shown in FIGS. 1 and 2, respectively. FIG. 1 depicts a typical line/space pattern with sub-10 μm resolution from a working formulation. FIG. 2 depicts a typical cracked film with insufficient physical properties that fails the solvent resistance test. The images in FIGS. 1 and 2 were imaged with a Meiji Techno MT9430 optical microscope at 100× magnification.

The following describes one example of file retention testing. The thicknesses of the films is measured before and after pattern curing with a Bruker Dektak DXT-E profilometer. The ratio of measured thickness after pattern curing to before pattern curing is defined as the film retention.

Below are descriptions of specific samples of the compositions described herein. Using the procedures described above, samples 1-5 and comparative samples 6-10 were prepared as listed in Table 2 below along with the results for the solvent resistance and film retention tests on the resultant cured films.

TABLE 2

| | | | | | | Film |
|---|---|---|---|---|---|---|
| | Polymer | DNQ PAC | Solvent | Additive | Pass solvent | retention |
| Samples | (wt %) | (wt %) | (wt %) | (wt %) | resistance test | (%) |
| Sample 1 | P1 (7.69) | C1 (2.31) | NMP (90.0) | | Y | 100 |
| Sample 2 | P2 (7.69) | C1 (2.31) | GBL (90.0) | | Y | 99 |
| Sample 3 | P1 (7.69) | C2 (2.31) | GBL/PGME | | Y | 99 |
| | | | (10.0/80.0) | | | |
| Sample 4 | P2 (7.69) | C2 (2.31) | GBL/PGME | | Y | 100 |
| | | | (20.0/70.0) | | | |
| Sample 5 | P1 (7.98) | C1 (2.30) | GBL/PGME | | Y | 97 |
| | | | (19.9/69.8) | | | |
| Comparative | P3 (7.69) | C1 (2.31) | GBL/PGME | | N | 100 |
| Sample 6 | | | (20.0/70.0) | | | |
| Comparative | P4 (7.69) | C3 (2.31) | GBL/PGME | | N | 101 |
| Sample 7 | | | (20.0/70.0) | | | |
| Comparative | P1 (8.00) | C3 (2.00) | GBL/PGME | | N | 101 |
| Sample 8 | | | (20.0/70.0) | | | |
| Comparative | P5 (8.00) | C3 (2.00) | GBL/PGME | | N | 99 |
| Sample 9 | | | (20.0/70.0) | | | |
| Comparative | P5 (7.76) | C3 (2.00) | GBL/PGME | D1 (0.30) | Y | 98 |
| Sample 10 | | | (20.0/70.0) | | | |

### Samples 1-5 and Comparative Samples 6-10; Solvent Resistance and Film Retention

Samples 1, 2, 3, 4 and 5 demonstrate that if a positive photosensitive composition has a polymer with alkynyl units in the polymer chain and the chain ends, a benzophenone type DNQ PAC, and an appropriate solvent or solvent mixture, cured patterned films with good solvent resistance and film retention and can be achieved without additional additives. Comparative samples 6 and 7 demonstrate that if a positive photosensitive composition polymer has alkynyl units in the chain ends but not in the polymer chain, it will not have the properties needed for a patterned cured film that passes the solvent resistance test. Comparative samples 8 and 9 demonstrate that if a positive photosensitive composition polymer has alkynyl units in the polymer chain but not in the polymer chain ends, it will not have the properties needed for a patterned cured film that passes the solvent resistance test. Comparative sample 10 demonstrates that by introducing an additive that a positive photosensitive composition polymer with alkynyl units in the polymer chain but not in the polymer chain end, like comparative sample 9, can be used to make cured patterned films with good solvent resistance and film retention.

The foregoing description of examples has been presented for purposes of illustration and description. It is not intended to be exhaustive or limiting to the forms described. Numerous modifications are possible in light of the above teachings. Some of those modifications have been discussed, and others will be understood by those skilled in the art. The examples were chosen and described in order to best illustrate principles of various examples as are suited to particular uses contemplated. The scope is, of course, not limited to the examples set forth herein, but can be employed in any number of applications and equivalent devices by those of ordinary skill in the art.

We claim:

1. A positive type photosensitive composition that includes a polymer with alkynyl structures in the polymer chain and chain ends made by a condensation reaction.

2. The positive type photosensitive composition of claim 1, wherein the concentrated reaction is between diamines and dianhydrides yielding a polyamic acid, polyamic ester, polyimide, or a combination of the forgoing.

3. The positive type photosensitive composition of claim 1, wherein the polymer dianhydride is 4,4′-(ethyne-1,2-diyl) diphthalic anhydride (EDDPA) or a combination of dianhydrides with EDDPA and other dianhydrides including 4,4′-oxydiphthalic anhydride (ODPA).

4. The positive type photosensitive composition of claim 1, wherein the polymer diamine is either 2,2-Bis(3-(3-aminobenzoylamino)-4-hydroxyphenyl), hexafluoropropane (6FAPDA), 2,2-Bis(3-amino-4-hydroxyphenyl) hexafluoropropane (6FAP), or a combination of diamines including 6FAPDA and/or 6FAP.

5. The positive type photosensitive composition of claim 1 wherein the polymer has acetylene type endcappers.

6. The positive type photosensitive composition of claim 5, wherein, the endcappers include either 3-ethynylaniline (3EA), 4-ethynylaniline (4EA), or a combination of endcappers including 3EA and/or 4EA.

7. The positive type photosensitive composition of claim 1, further comprising 6.0-9.0 wt % of the polymer, 1.5-3.0 wt % benzophenone type diazonaphthoquinone (DNQ) compound as a PAC, and 88.0-92.5 wt % of solvents.

8. The positive photosensitive composition of claim 7, wherein the PAC is a benzophenone type DNQ.

9. The positive photosensitive composition of claim 8, wherein the benzophenone type DNQ includes either 2,1,4-DNQ or 2,1,5-DNQ, or a combination of benzophenone type DNQs including 2,1,4-DNQ and/or 2,1,5-DNQ.

10. The positive photosensitive composition of claim 8, where the solvent includes one or a combination of N-methyl-2-pyrrolidone (NMP), gamma-Butyrolactone (GBL), Ethyl lactate (EL), Propylene glycol methyl ether (PGME), and Propylene glycol methyl ether acetate (PGMEA).

11. The positive photosensitive composition of claim 7, wherein a cured film is prepared from the positive type photosensitive composition.

12. The positive photosensitive composition of claim 11, wherein the cured film is used to form an electronic device.
